(19) United States
(12) Patent Application Publication
(10) Pub. No.: US 2005/0045916 A1
(43) Pub. Date: Mar. 3, 2005

(54) Power voltage line layout of semiconductor cells using active area

(75) Inventor: Yong-Seop Kim, Yongin-si (KR)

Correspondence Address: Anthony P. Onello, Jr.;MILLS & ONELLO LLP, Suite 605, Eleven Beacon Street, Boston, MA, 02108, US

(73) Assignee: Samsung Electronics Co., Ltd.

(21) Appl. No.: 10/869,409

(22) Filed: Jun. 16, 2004

(30) Foreign Application Priority Data
Aug. 28, 2003 (KR) 03-59826

(51) Int. Cl. H01L 27/10

(52) U.S. Cl. 257/202

(57) ABSTRACT

In a semiconductor integrated circuit layout, a power voltage line for supplying a power voltage to the semiconductor integrated circuit is connected to an active area where an NMOS transistor and/or a PMOS transistor are formed, by using the active area. An active area is formed between an active area where the power voltage line and/or a ground voltage line are formed and the active area where the NMOS transistor and/or the PMOS transistor are formed. In this manner, the active area where the power voltage line and/or the ground voltage line are formed and the active area where the NMOS transistor and/or the PMOS transistor are formed are connected.

### CROSS REFERENCE TO RELATED APPLICATION

This application claims the priority of Korean Patent Application No. 2003-59826, filed on Aug. 28, 2003, in the Korean Intellectual Property Office, the disclosure of which is hereby incorporated by reference in its entirety.

### BACKGROUND OF THE INVENTION

1. Field of the Invention

The present invention relates to a layout of a semiconductor device, and more particularly, to a semiconductor integrated circuit in which a power voltage and a ground voltage are connected to a NMOS transistor and a PMOS transistor.

2. Description of the Related Art

When designing the library cell layout of a general semiconductor device, power voltage and ground voltage are directly supplied to an NMOS transistor and/or a PMOS transistor for application to the NMOS transistor and/or the PMOS transistor. In other words, in the library cell layout, a power voltage line and a ground voltage line are arranged in parallel with each other and the PMOS transistor and the NMOS transistor are arranged between the power voltage line and the ground voltage line. In order to connect the NMOS transistor and/or the PMOS transistor to the power voltage and the ground voltage, a line through which the power voltage flows, a line connected to the ground voltage, and an active region where the NMOS transistor and/or the PMOS transistor are formed are connected by a metal. Here, the active region indicates a region, or area, of the semiconductor cell in which a MOS transistor or a voltage line is formed.

FIG. 1 illustrates a cell layout according to a conventional library cell layout design approach. Referring to the example of FIG. 1, the cell layout is used to design a NOR gate shown in FIG. 2. A power voltage line 100 is formed in a power voltage active area 142. Also, a ground voltage line 110 is formed in a ground voltage active area 144. A contact 160 is formed to connect the power voltage active area 142 to the power voltage line 100 and a contact 162 is formed to connect the ground voltage active area 144 to the ground voltage line 110. At least two contacts (e.g., the contacts 160 and 162) are formed in each voltage line 100, 110 at regular intervals for the purpose of improving the reliability of connection.

A PMOS transistor is formed in a PMOS active area 140 and an NMOS transistor is formed in an NMOS active area 146. A power voltage feeder 130 is arranged across the power voltage line 100 and the PMOS active area 140. A source contact 150 is used to connect this power voltage feeder 130 and the PMOS active area 140. In this manner, the power voltage line 100 and the PMOS active area 140 are connected.

A metal line 136 is formed to connect the PMOS active area 140 and the NMOS active area 146. A drain contact 156 is formed to connect the metal line 136 and the PMOS active area 140, and a drain contact 158 is formed to connect the metal line 136 and the NMOS active area 146.

Two gate electrodes 120 are formed across the PMOS transistor and the NMOS transistor. Gate contacts 152_A and 152_B are formed in a central portion of the gate electrodes 120, so as to connect the gate electrodes 120 with external signals.

Ground voltage feeders 132 and 134 are connected to the ground voltage line 110. Source contacts 154 are formed to connect the ground voltage feeder to the NMOS transistor.

FIG. 2 is a circuit diagram of the NOR gate of FIG. 1. Referring to FIGS. 1 and 2, inputs Input_A and an input Input_B are input through the gate electrodes 120 and an output signal OUTPUT is output through the metal line 136. A current flows through the right and left sides of the PMOS active area 140 and the NMOS active area 146 according to signals applied to the gate electrodes 120, and thus, the NOR gate as shown in FIG. 2 is configured.

In a conventional layout design as shown in FIG. 1, source contacts (e.g., the source contacts 150 and 154) are used to connect metal runs (e.g., the power voltage feeder 130 and the ground voltage feeders 132 and 134) and active areas (e.g., the PMOS active area 140 and the NMOS active area 146). Also, there has been a recent tendency to use at least two such source contacts 150, 154 for the purpose of improving the accuracy and reliability of the connection. As a consequence of the use of additional redundant contacts, there is a greater likelihood that a contact may not be formed in the intended location during the semiconductor manufacturing process. In addition, the use of redundant contacts can also lead to increased resistance at the junction. Moreover, on account of space shortage, arrangement of metal lines in a semiconductor cell may be restricted as a result of the additional contacts.

### SUMMARY OF THE INVENTION

The present invention provides a semiconductor cell layout in which the use of unnecessary contacts is mitigated or eliminated, and in which an area required for a metal line required for a dual via configuration can be readily secured.

The present invention also provides a semiconductor cell layout, in which contact issues that may occur during a semiconductor manufacturing process can be solved due to a reduction of the use of unnecessary contact and an increase in a resistance can be prevented.

In one aspect, the present invention is directed to a semiconductor integrated circuit. In a first active area, a MOS transistor is formed. In a second active area, a first voltage line is formed. At least one third active area electrically connects the first and second active areas to each other.

In one embodiment, the MOS transistor is a PMOS transistor or an NMOS transistor, and the first voltage is a power voltage or a ground voltage.

In another aspect, the present invention is directed to a semiconductor integrated circuit. In a first active area, a PMOS transistor is formed. In a second active area, a power voltage line is formed. At least one third active area electrically connects the first and second active areas to each other.

In one embodiment, the semiconductor integrated circuit further comprises a fourth active area in which an NMOS transistor is formed; a fifth active area in which a ground voltage line is formed; and at least one sixth active area that electrically connects the fourth and fifth active areas to each other. In another embodiment, the semiconductor integrated circuit further comprises a power voltage line, which supplies the power voltage; and at least one first contact, which is formed to electrically connect the power voltage line with the second active area. In another embodiment, a ground voltage line supplies the ground voltage; and at least one second contact electrically connects the ground voltage line with the fifth active area.

In another embodiment, the semiconductor integrated circuit further comprises a first metal line, which is formed in the first active area and the fourth active area, and couples the first active area and the fourth active area; at least one third contact, which is formed to electrically connect the first active area with the first metal line; and at least one fourth contact, which is formed to electrically connect the fourth active area with the first metal line. A gate electrode is formed in parallel with a portion of the first metal line and across the first and fourth active areas and divides each of the first and fourth active areas into at least two areas.

### BRIEF DESCRIPTION OF THE DRAWINGS

The above and other aspects and advantages of the present invention will become more apparent by describing in detail exemplary embodiments thereof with reference to the attached drawings in which:

FIG. 1 illustrates a cell layout of a NOR gate according to a conventional library cell layout design technique;

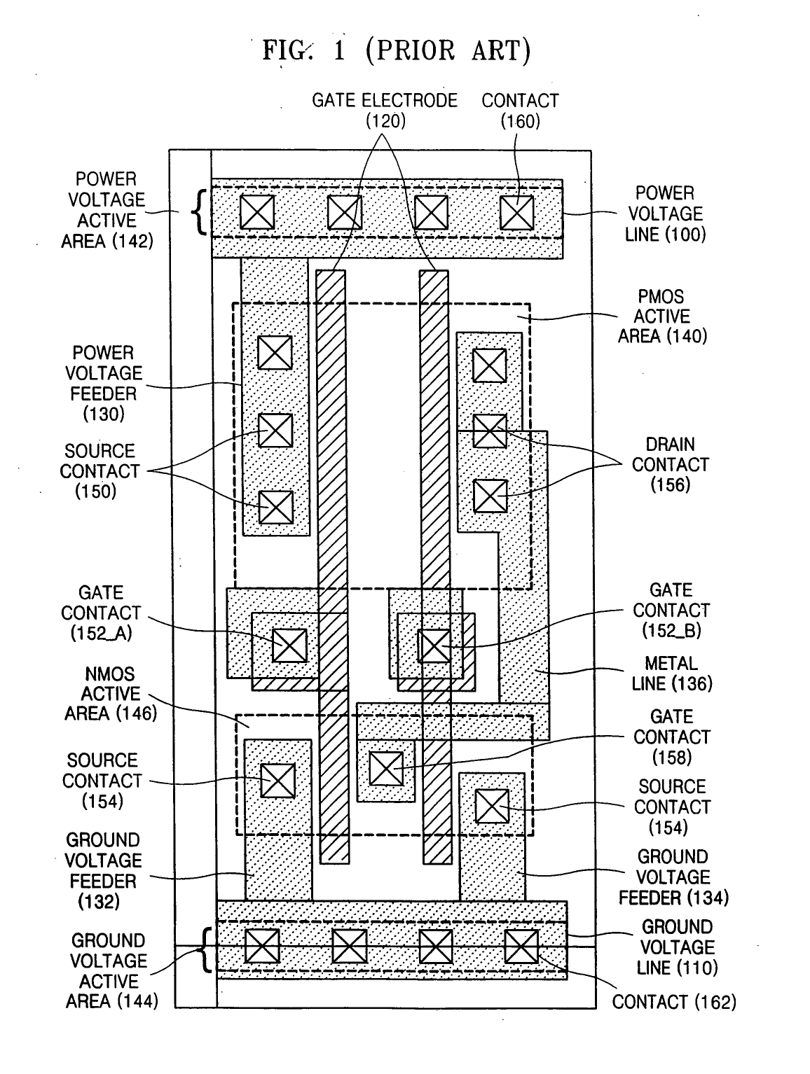

FIG. 2 is a circuit diagram of an NOR gate of FIG. 1; and

FIG. 3 illustrates a semiconductor cell layout according to an embodiment of the present invention.

### DETAILED DESCRIPTION OF THE INVENTION

The present invention will now be described more fully with reference to the accompanying drawings, in which a preferred embodiment of the invention is shown. In the drawings, like reference numerals are used to refer to like elements throughout.

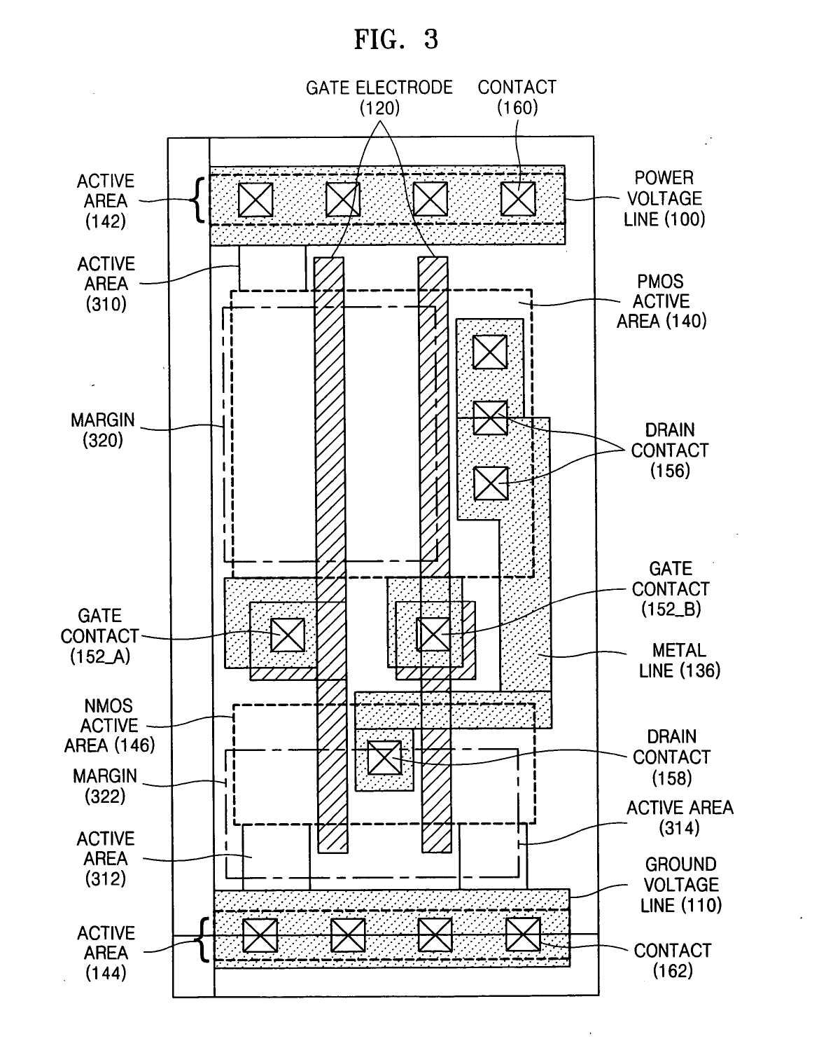

FIG. 3 illustrates a semiconductor cell layout according to an embodiment of the present invention.

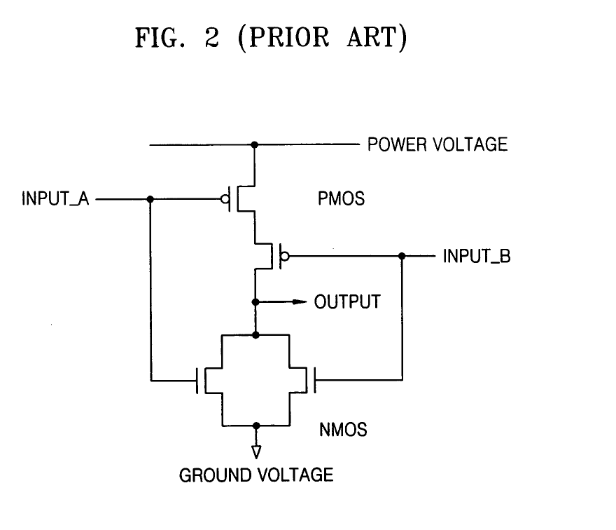

Referring to FIG. 3, the NOR gate of FIG. 2 is shown according to a cell layout of the present invention. First, the power voltage line 100 and the ground voltage line 110 are arranged in parallel with each other, and a PMOS transistor and an NMOS transistor are formed in a PMOS active area 140 and NMOS active area 146 respectively, between the power voltage line 100 and the ground voltage line 110. The power voltage line 100 is connected to an active area 142 at contact 160, and the ground voltage line 110 is connected to an active area 144 at contact 162.

An active area 310 is formed between the active area 142 of the power voltage line 100 and the PMOS active area 140, in order to electrically connect the two active areas 140 and 142. Also, active areas 312 and 314 are physically connected between the active area 144 of the ground voltage line 110 and the NMOS active area 146 to electrically connect the two active areas 144 and 146.

The PMOS transistor is formed in the PMOS active area 140 and the NMOS transistor is formed in the NMOS active area 144. Thus, the power voltage line 100 and the PMOS active area 140 are connected through the active area 310, and the ground voltage line 110 and the NMOS active area 146 are connected through the active areas 312, 314.

A metal line 136 is formed to connect the PMOS active area 140 and the NMOS active area 146. A drain contact 156 is formed to connect the metal line 136 and the PMOS active area 140. A drain contact 158 is formed to connect the metal line 136 and the NMOS active area 146.

Two gate electrodes 120 are formed across the PMOS transistor and the NMOS transistor. Gate contacts 152_A and 152_B are formed in the middle of gate electrodes 120, so as to connect the gate electrodes 120 with externally applied signals.

In this manner, a current flowing through the power voltage line 100 flows into the active area 142 through the contact 160. The current flows into the PMOS active area 140 of the PMOS transistor through the active area 310 that is directly connected to the active area 142 and then flows into the metal line 136 through the drain contact 156 of the PMOS transistor. Then, the current flows into the NMOS active area 146 through the drain contact 158 of the NMOS transistor and then flows into the NMOS active area 144 through the active areas 312 and 314 that are directly connected to the NMOS active area 146. Finally, the current flows into the ground voltage line 100 through the contact 162 that is connected to the NMOS active area 144.

Through the cell layout of the present invention, the active area 142 of the power voltage 142 and the active area 140 of the PMOS transistor are connected to each other directly by active area 310. In addition, the active area 144 of the ground voltage and the active area 146 of the NMOS transistor are connected to each other directly by multiple active areas 312, 314. In this manner, the need for metal lines for connecting the respective active areas is eliminated, and therefore, the use of metal contacts for connecting the above-lying metal lines to the underlying active areas is likewise eliminated. As a result, additional margins 320 and 322, which otherwise would have been consumed by contacts, are provided as shown in FIG. 3. As a result, metal lines can be arranged in the margins 320 and 322 for other purposes, such as additional line routing.

In addition, the present invention reduces the number of contacts used between the active layer and the metal line, thereby reducing the likelihood of connectivity errors associated with misalignment of the contacts.

While the present invention has been particularly shown and described with reference to exemplary embodiments thereof, it will be understood by those of ordinary skill in the art that various changes in form and details may be made therein without departing from the spirit and scope of the invention as defined by the appended claims and their equivalents.

1. A semiconductor integrated circuit comprising:
a first active area in which a MOS transistor is formed;
a second active area in which a first voltage line is formed; and
at least one third active area that electrically connects the first and second active areas to each other.

2. The semiconductor integrated circuit of claim 1, wherein the MOS transistor is a PMOS transistor or an NMOS transistor.

3. The semiconductor integrated circuit of claim 1, wherein the first voltage is a power voltage or a ground voltage.

4. A semiconductor integrated circuit comprising:
a first active area in which a PMOS transistor is formed;
a second active area in which a power voltage line is formed; and
at least one third active area that electrically connects the first and second active areas to each other.

5. The semiconductor integrated circuit of claim 4, further comprising:
a fourth active area in which an NMOS transistor is formed,
a fifth active area in which a ground voltage line is formed; and
at least one sixth active area that electrically connects the fourth and fifth active areas to each other.

6. The semiconductor integrated circuit of claim 4, further comprising:
a power voltage line, which supplies the power voltage; and
at least one first contact, which is formed to electrically connect the power voltage line with the second active area.

7. The semiconductor integrated circuit of claim 5, further comprising:
a ground voltage line, which supplies the ground voltage; and
at least one second contact, which is formed to electrically connect the ground voltage line with the fifth active area.

8. The semiconductor integrated circuit of claim 5, further comprising:
a first metal line, which is formed in the first active area and the fourth active area, and couples the first active area and the fourth active area;
at least one third contact, which is formed to electrically connect the first active area with the first metal line; and
at least one fourth contact, which is formed to electrically connect the fourth active area with the first metal line.

9. The semiconductor integrated circuit of claim 8, further comprising a gate electrode which is formed in parallel with a portion of the first metal line and across the first and fourth active areas and divides each of the first and fourth active areas into at least two areas.
